(19) United States
(12) Patent Application Publication
(10) Pub. No.: US 2022/0164064 A1
(43) Pub. Date: May 26, 2022

(54) TRANSPARENT CONDUCTIVE FILM AND TOUCH PANEL COMPRISING THE SAME

(71) Applicant: Cambrios Film Solutions Corporation, Tortola (VG)

(72) Inventors: Chung-Chin Hsiao, Hsinchu County (TW); Siou-Cheng Lien, Miaoli County (TW); Chia-Yang Tsai, New Taipei City (TW); Yi-Wen Chiu, Taoyuan City (TW)

(21) Appl. No.: 16/953,749

(22) Filed: Nov. 20, 2020

(51) Int. Cl. G06F 3/044; H05K 1/02; H05K 1/09

(52) U.S. Cl. CPC G06F 3/0446; H05K 1/032; H05K 1/09; H05K 1/0296

(57) ABSTRACT

A transparent conductive film and a touch panel comprising the same are disclosed. The transparent conductive film comprises a substrate and a conductive mesh film disposed on the substrate. The conductive mesh film comprises a plurality of cross-bonded silver nanowires, and a rate of change of resistance of the conductive mesh film is smaller than 1% after bending the transparent conductive film over 250,000 times.

### BACKGROUND OF THE DISCLOSURE

### 1. Field of the Disclosure

The present disclosure relates to a transparent conductive film and a touch panel comprising the same. More particularly, the present disclosure relates to a transparent conductive film for flexible touch panels and a touch panel comprising the same.

### 2. Description of Related Art

Recently, the application of touch panels is becoming more extensive. More and more electronic products are equipped with touch panels to provide the functions of direct operation or issuing commands for making those electronic products user-friendly. In particular, the demand for flexible touch panels is increasing. To meet the demand, many conductive materials have emerged to replace indium tin oxide (ITO) in recent years to provide excellent flexibility and conductivity.

Copper mesh film is often applied as the conductive film in touch panels for replacing the ITO film. However, the copper mesh has always had optical issues, such as a high yellowing index (b* value) and light reflection. Also, the reflection of the regular copper mesh pattern is prone to constructive interference and causing the so-called moire effect.

To avoid affecting transparency due to the optical issues of the copper mesh, a blackening treatment may be performed on the copper mesh to lower its visibility or the linewidth of the copper mesh may be lowered. However, performing the blackening treatment or lowering the linewidth of the copper mesh may lengthen the preparation step, lower the yield, and increase the preparation cost.

Silver nanowires have high conductivity and excellent flexibility, but the silver nanowires may generate surface plasma resonance effect and ultraviolet light having a wavelength of 320 nm to 420 nm may be absorbed when using the silver nanowires as the conductive film. Therefore, the color of the conductive film prepared by the silver nanowires is yellow, which affects the color of the output image of the display panel.

Accordingly, a novel transparent conductive film and a touch panel comprising the same are needed to improve the optical issues and the yield when preparing the flexible transparent conductive film using the copper mesh or the silver nanowires and also to provide excellent conductivity.

### SUMMARY OF THE DISCLOSURE

The present disclosure provides a novel transparent conductive film, which comprises a substrate and a conductive mesh film disposed on the substrate. The conductive mesh film comprises a plurality of cross-bonded silver nanowires, and a rate of change of resistance of the conductive mesh film is smaller than 1% after bending the transparent conductive film over 250,000 times.

In one embodiment, a transparency of the transparent conductive film to visible light (having a wavelength between 400 nm and 700 nm) is greater than 90%.

In one embodiment, the conductive mesh film comprises a plurality of silver nanowire areas and a plurality of blank areas. The cross-bonded silver nanowires are disposed in the silver nanowire areas, a linewidth of each of the silver nanowire areas is 1 μm to 10 μm, and an area of each of the blank areas is 100 μm² to 200 μm².

In one embodiment, a ratio of a total area of the blank areas to an area of the conductive mesh film is 0.9 to 0.999.

In one embodiment, the conductive mesh film further comprises a hard-coated layer for coating or covering the cross-bonded silver nanowires.

In one embodiment, the substrate comprises a display zone and a non-display zone, and the conductive mesh film is disposed on the display zone.

In one embodiment, the transparent conductive film further comprises a plurality of conducting wires disposed on the non-display zone of the substrate and electrically connected to the conductive mesh film, wherein the conducting wires comprise a plurality of cross-bonded silver nanowires.

The present disclosure also provides a touch panel, which comprises a first substrate having a first surface and a second surface opposing the first surface, a first conductive mesh film disposed on the first surface of the first substrate, and a second conductive mesh film disposed above the first surface of the first substrate or disposed on the second surface of the first substrate. The first conductive mesh film and the second conductive mesh film comprise a plurality of cross-bonded silver nanowires, and a rate of change of resistance of the first conductive mesh film and the second conductive mesh film is smaller than 1% after bending the touch panel over 250,000 times.

In one embodiment, the touch panel further comprises a second substrate and an adhesive layer. The second substrate comprises a first surface and a second surface opposing the first surface, the second conductive mesh film is disposed on the first surface of the second substrate, and the adhesive layer is disposed between the second surface of the second substrate and the first conductive mesh film.

In one embodiment, the second conductive mesh film is disposed on the second surface of the first substrate.

In one embodiment, the touch panel further comprises an insulating layer disposed on the first conductive mesh film, wherein the second conductive mesh film is disposed on the insulating layer.

In one embodiment, the first conductive mesh film and the second conductive mesh film respectively have a plurality of silver nanowire areas and a plurality of blank areas. The cross-bonded silver nanowires are disposed in the silver nanowire areas, a linewidth of each of the silver nanowire areas is 1 μm to 10 μm, and an area of each of the blank areas is 100 μm² to 200 μm².

In one embodiment, a ratio of a total area of the blank areas to an area of the first conductive mesh film is 0.9 to 0.999, and a ratio of a total area of the blank areas to an area of the second conductive mesh film is 0.9 to 0.999.

In one embodiment, the first conductive mesh film and the second conductive mesh film respectively include a hard-coated layer for coating or covering the cross-bonded silver nanowires.

In one embodiment, the first substrate comprises a display zone and a non-display zone, the first conductive mesh film is disposed in the display zone, and the second conductive mesh film is disposed with respect to the display zone.

In one embodiment, the touch panel further comprises a plurality of first conducting wires and a plurality of second conducting wires. The first conducting wires are disposed on the non-display zone and are electrically connected to the first conductive mesh film, the second conducting wires are disposed with respect to the non-display zone and are electrically connected to the second conductive mesh film, and the first conducting wires and the second conducting wires are formed by a plurality of cross-bonded silver nanowires respectively.

### BRIEF DESCRIPTION OF THE DRAWINGS

FIG. 1 is a sectional view of a transparent conductive film of a first embodiment of the present disclosure;

FIG. 2 is a top view of a first transparent conductive film of the first embodiment of the present disclosure;

FIG. 3 is a sectional view of a touch panel of a second embodiment of the present disclosure;

FIG. 4 is a sectional view of a substrate and a silver nanowire layer of the second embodiment of the present disclosure;

FIG. 5 is a sectional view of patterning the silver nanowire layer of the structure shown in FIG. 4 of the second embodiment of the present disclosure;

FIG. 6 is a sectional view of attaching a first transparent conductive film and a second transparent conductive film of the second embodiment of the present disclosure;

FIG. 7 is a sectional view of a touch panel of a third embodiment of the present disclosure;

FIG. 8 is a sectional view of the substrate and the silver nanowire layer of the third embodiment of the present disclosure;

FIG. 9 is a sectional view of patterning a silver nanowire layer of the structure shown in FIG. 8 of the third embodiment of the present disclosure;

FIG. 10 is a sectional view of a fourth embodiment of the present disclosure;

FIG. 11 is a sectional view of a display panel and a silver nanowire layer of the fourth embodiment of the present disclosure;

FIG. 12 is a sectional view of patterning the silver nanowire layer of the structure shown in FIG. 11 of the fourth embodiment of the present disclosure;

FIG. 13 is a sectional view of forming an insulating layer on the structure shown in FIG. 12 of the fourth embodiment of the present disclosure;

FIG. 14 is a sectional view of forming the silver nanowire layer on the structure shown in FIG. 13 of the fourth embodiment of the present disclosure;

FIG. 15 shows images of a metal mesh of Example 1, Comparative example 1, and Comparative example 2 of a bending test of the present disclosure; and

FIG. 16 shows the test result of the bending test of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

It will be understood that, in the description herein and throughout the claims that follow, when an element is referred to as being “connected” or “coupled” to another element, the element can be directly connected or coupled to the other element or intervening elements may be present.

It should be noted that the term “on” in the specification may be used herein to describe the relative positions between components. For example, a conductive mesh film disposed “on” a substrate includes embodiments in which the conductive mesh film is formed in direct contact with the substrate, and may also include embodiments in which additional components may be formed between the conductive mesh film and the substrate.

It will be understood that, in the description herein and throughout the claims that follow, although the terms “first,” “second,” and “third” and etc. may be used to describe various elements, these elements should not be limited by these terms. These terms are only used to distinguish one element from another for ease of description and are not related to the numbers or the orders. For example, “first conductive mesh film” and “second conductive mesh film” can both be realized as “conductive mesh film”.

Any element in a claim that does not explicitly state “means for” performing a specified function, or “step for” performing a specific function, is not to be interpreted as a “means” or “step” clause as specified in 35 U.S.C. § 112(f). In particular, the use of “step of” in the claims herein is not intended to invoke the provisions of 35 U.S.C. § 112(f).

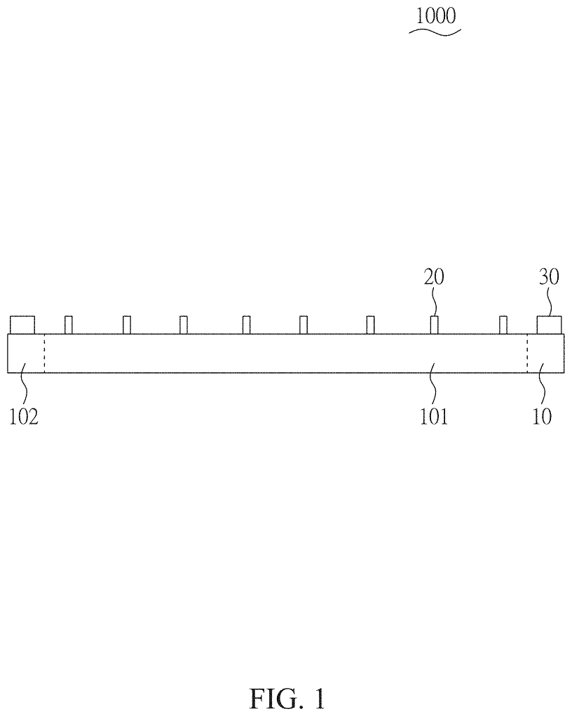

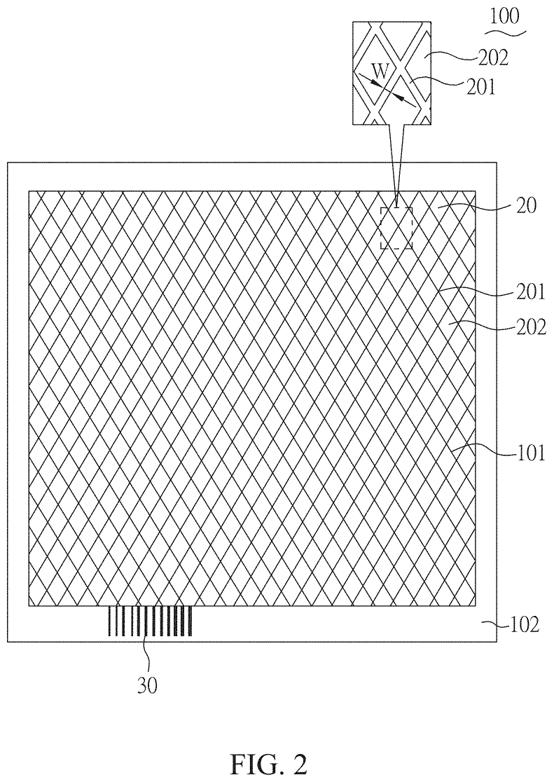

A sectional view and a top view of a transparent conductive film 1000 of a first embodiment of the present disclosure are shown in FIG. 1 and FIG. 2. The transparent conductive film 1000 comprises a substrate 10, a conductive mesh film 20, and a plurality of conducting wires 30. The substrate 10 provides mechanical support or protection for the conductive mesh film 20 and can be made of materials known in the art. Preferably, the substrate 10 is made of flexible materials such as polyvinyl chloride (PVC), polypropylene (PP), polyethylene terephthalate (PET), cycloolefin polymer (COP), polyethylene naphthalate (PEN), triacetate (TAC), polycarbonate (PC), Polystyrene (PS), polyimide (PI), or the like. In the present embodiment, the substrate 10 includes a display zone 101 and a non-display zone 102, the conductive mesh film 20 is disposed on the display zone 101 and the conducting wires 30 are disposed on the non-display zone 102.

Please refer to FIG. 2, the conductive mesh film 20 includes a plurality of silver nanowire areas 201 and a plurality of blank areas 202, wherein the silver nanowire areas 201 are formed by a plurality of cross-bonded silver nanowires and the blank areas 202 are surrounded and defined by the silver nanowire areas 201. A linewidth W of the silver nanowire areas 201 is 1 μm² to 10 μm, an area of each of the blank areas 202 is 100 μm² to 200 μm². A ratio of a total area of the blank areas 202 to an area of the conductive mesh film 20 is 0.9 to 0.999. The conducting wires 30 are also formed by a plurality of cross-bonded silver nanowires and are electrically connected to the conductive mesh film 20.

In other embodiments of the present disclosure, the shapes of the silver nanowire areas 201 and the blank areas 202 are not particularly limited, wherein the shape of the blank areas 202 may be circle, oval, or polygons.

In other embodiments of the present disclosure, the conductive mesh film 20 may further comprise a hard-coated layer, which covers the silver nanowires or is coated on the silver nanowires for further protections and improving the durability of the silver nanowires.

The preparation method of the transparent conductive film 1000 of the present embodiment includes the steps of forming a silver nanowire layer on the substrate 10 (including the display zone 101 and the non-display zone 102); and patterning the silver nanowire layer through a photoresist exposure and development process to form the conductive mesh film 20 on the display zone 101 and to form the conducting wires 30 on the non-display zone 102.

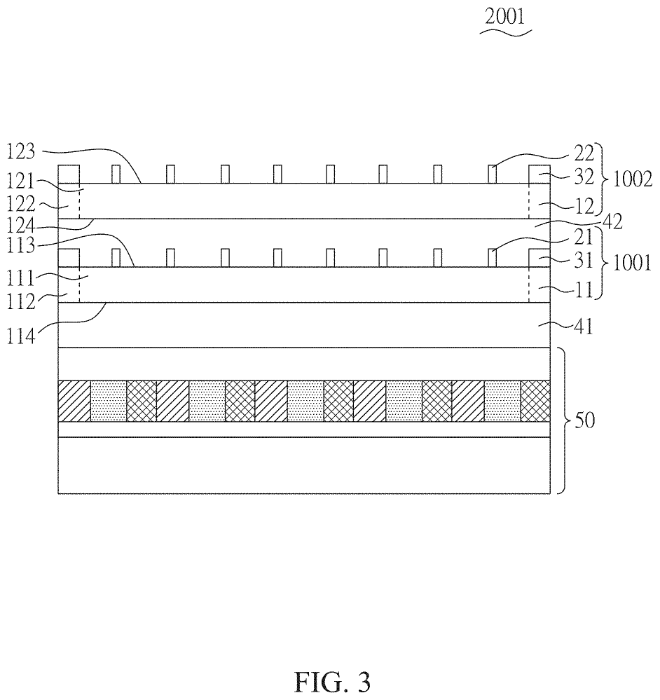

A touch panel 2001 of a second embodiment of the present disclosure is shown in FIG. 3. The touch panel 2001 comprises a first transparent conductive film 1001, a second transparent conductive film 1002, a first adhesive layer 41, a second adhesive layer 42, and a display panel 50.

The first transparent conductive film 1001 is attached to the display panel 50 through the first adhesive layer 41, and the second transparent conductive film 1002 is attached to the first transparent conductive film 1001 through the second adhesive layer 42. That is, the first adhesive layer 41 is disposed between the display panel 50 and the first transparent conductive film 1001, and the second adhesive layer 42 is disposed between the first transparent conductive film 1001 and the second transparent conductive film 1002.

The first transparent conductive film 1001 comprises a first substrate 11, a first conductive mesh film 21, and first conducting wires 31, wherein the first substrate 11 includes a display zone 111, a non-display zone 112, a first surface 113, and a second surface 114 opposing the first surface 113. The first conductive mesh film 21 is formed on the first surface 113 in the display zone 111 of the first substrate 11, and the first conducting wires 31 are formed on the first surface 113 in the non-display zone 112 of the first substrate 11. Similarly, the second transparent conductive film 1002 includes a second substrate 12, a second conductive mesh film 22, and second conducting wires 32, wherein the second substrate 12 includes a display zone 121, a non-display zone 122, an upper surface 123, and a lower surface 124 opposing the upper surface 123. The second conductive mesh film 22 is formed on the upper surface 123 in the display zone 121 of the second substrate 12, and the second conducting wires 32 are formed on the upper surface 123 in the non-display zone 122 of the second substrate 12. The second adhesive layer 42 is disposed between the lower surface 124 of the second substrate 12 and the first conductive mesh film 21 for attaching the first transparent conductive film 1001 and the second transparent conductive film 1002.

The first conductive mesh film 21 and the second conductive mesh film 22 are similar to the conductive mesh film 20 of the first embodiment, which has a plurality of silver nanowire areas 201 and a plurality of blank areas 202, and the same description need not be repeated.

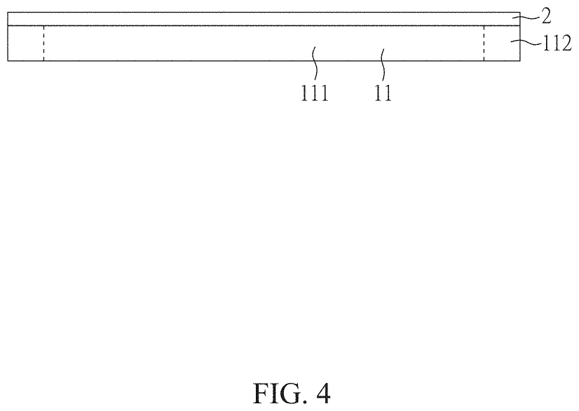

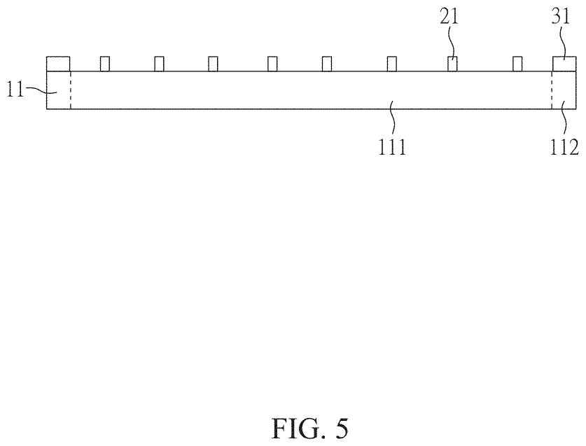

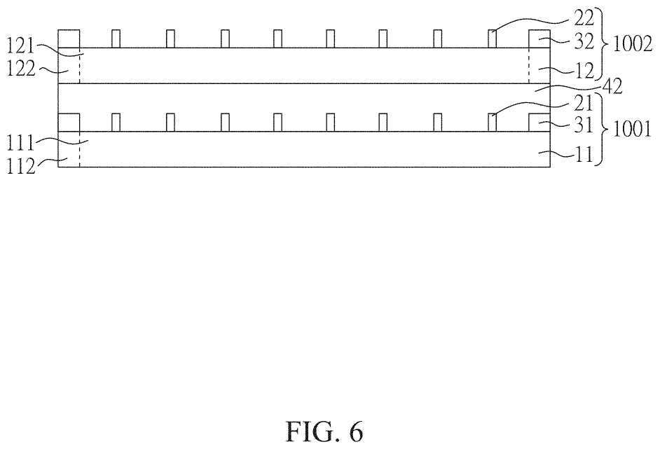

The preparation method of the touch panel 2001 of the present embodiment includes the steps of (1) coating a silver nanowire layer 2 on the first substrate 11 as shown in FIG. 4; (2) patterning the silver nanowire layer 2 through a photoresist exposure and development process to form the first transparent conductive film 1001 having the first conductive mesh film 21 disposed on the display zone 111 and the first conducting wires 31 disposed on the non-display zone 112 as shown in FIG. 5; (3) disposing a silver nanowire layer on the second substrate 12; (4) patterning the silver nanowire layer through a photoresist exposure and development process to form the second transparent conductive film 1002 having the second conductive mesh film 22 disposed on the display zone 121 and the second conducting wires 32 disposed on the non-display zone 122; (5) attaching the first transparent conductive film 1001 to the second transparent conductive film 1002 through the second adhesive layer 42 as shown in FIGS. 6; and (6) attaching the structure prepared in step (5) to the display panel 50 through the first adhesive layer 41 for finishing the touch panel 2001 shown in FIG. 3.

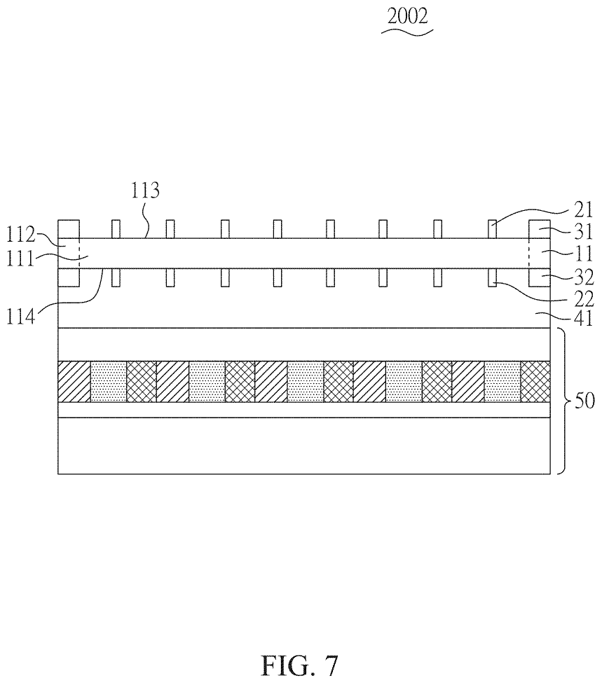

A touch panel 2002 of a third embodiment of the present disclosure is shown in FIG. 7. The touch panel 2002 comprises a first substrate 11, a first conductive mesh film 21, first conducting wires 31, a second conductive mesh film 22, second conducting wires 32, a first adhesive layer 41, and a display panel 50.

The first substrate 11 includes a display zone 111, a non-display zone 112, a first surface 113, and a second surface 114. The first conductive mesh film 21 is disposed on the first surface 113 in the display zone 111 of the first substrate 11, and the first conducting wires 31 are disposed on the first surface 113 in the non-display zone 112 of the first substrate 11. The second conductive mesh film 22 is disposed on the second surface 114 in the display zone 111 of the first substrate 11, and the second conducting wires 32 are disposed on the second surface 114 in the non-display zone 112 of the first substrate 11. The structure mentioned above is attached to the display panel 50 through the first adhesive layer 41.

The first conductive mesh film 21 and the second conductive mesh film 22 of the present embodiment are similar to the conductive mesh film 20 of the first embodiment, which has a plurality of silver nanowire areas 201 and a plurality of blank areas 202, and the same description need not be repeated.

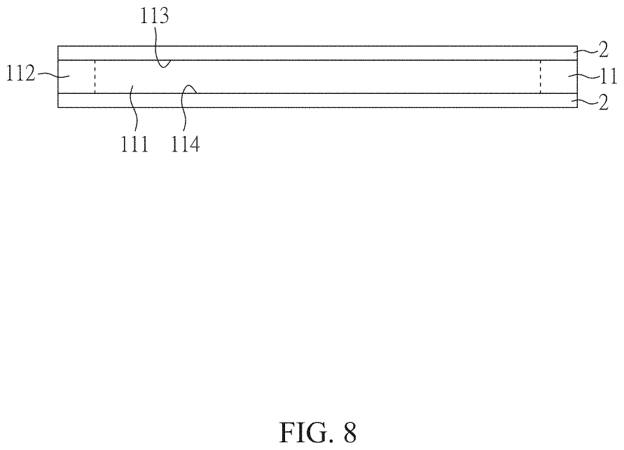

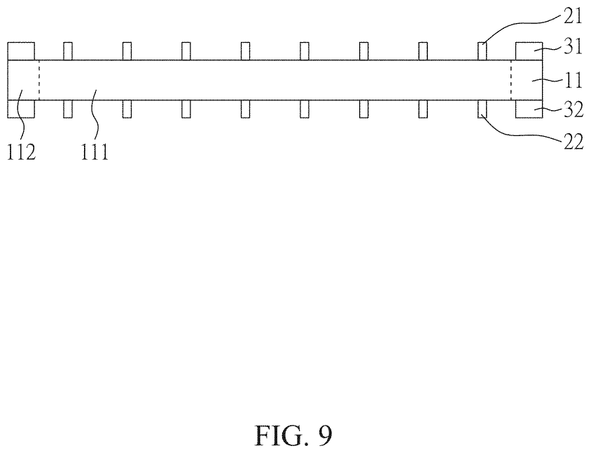

The preparation method of the touch panel 2002 of the present embodiment includes the steps of (1) coating silver nanowire layers 2 on the first surface 113 and the second surface 114 of the first substrate 11 as shown in FIG. 8; (2) patterning the silver nanowire layers 2 on the first surface 113 and the second surface 114 of the first substrate 11 through a photoresist exposure and development process as shown in FIG. 9, wherein the silver nanowire layer 2 on the first surface 113 is patterned to become the first conductive mesh film 21 on the display zone 111 and the first conducting wires 31 on the non-display zone 112, and the silver nanowire layer 2 on the second surface 114 is patterned to become the second conductive mesh film 22 on the display zone 111 and the second conducting wires 32 on the non-display zone 112; and (3) attaching the structure prepared in step (2) to the display panel 50 for finishing the touch panel 2002 shown in FIG. 7.

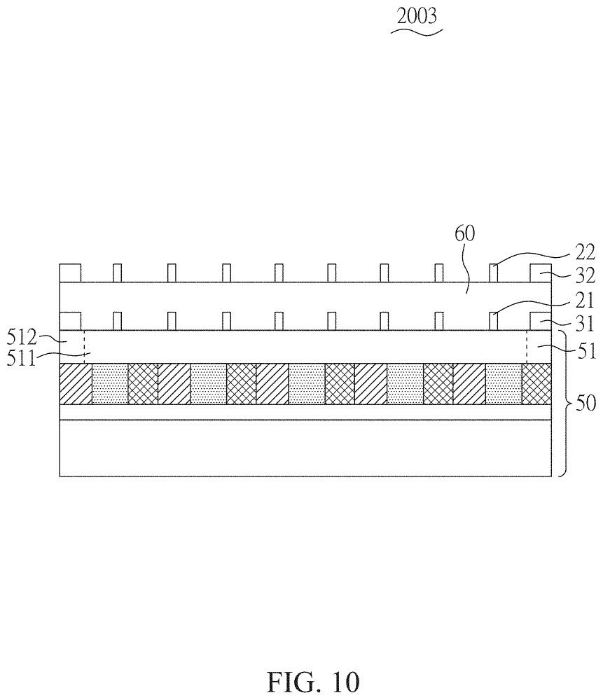

A touch panel 2003 of a fourth embodiment is shown in FIG. 10. The touch panel 2003 comprises a first conductive mesh film 21, first conducting wires 31, a second conductive mesh film 22, second conducting wires 32, an insulating layer 60, and a display panel 50.

In the present embodiment, a cap layer 51 of the display panel 50 is regarded as a substrate having a display zone 511 and a non-display zone 512. The first conductive mesh film 21 and the first conducting wires 31 are formed respectively in the display zone 511 and the non-display zone 512. The insulating layer 60 is disposed on the first conductive mesh film 21 and the first conducting wires 31, and the second conductive mesh film 22 and the second conducting wires 32 are formed on the insulating layer 60. The second conductive mesh film 22 is formed with respect to the display zone 511 and the second conducting wires 32 are formed with respect to the non-display zone 512.

The first conductive mesh film 21 and the second conductive mesh film 22 of the present embodiment are similar to the conductive mesh film 20 of the first embodiment, which has a plurality of silver nanowire areas 201 and a plurality of blank areas 202, and the same description need not be repeated.

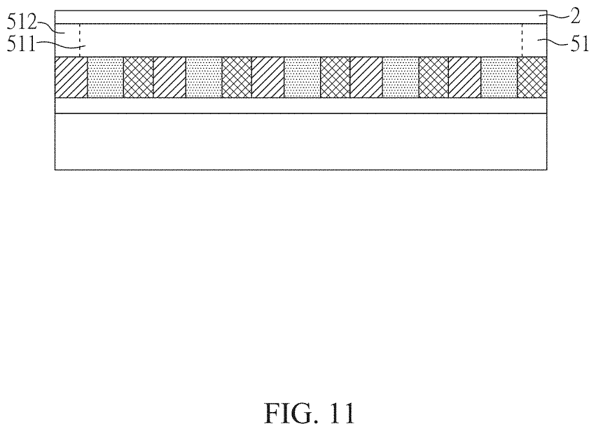

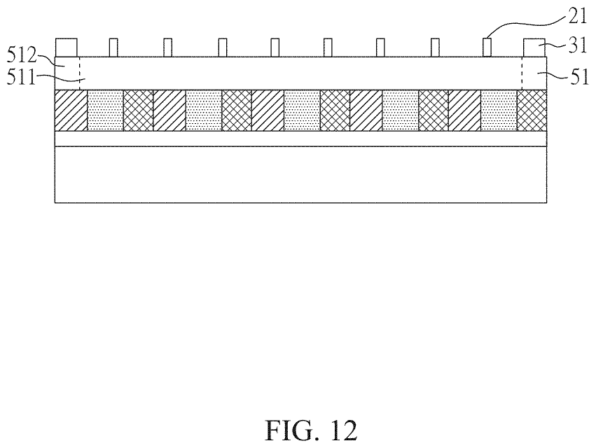

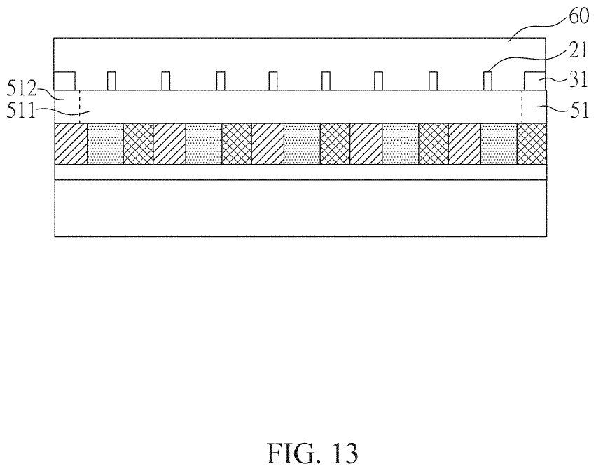

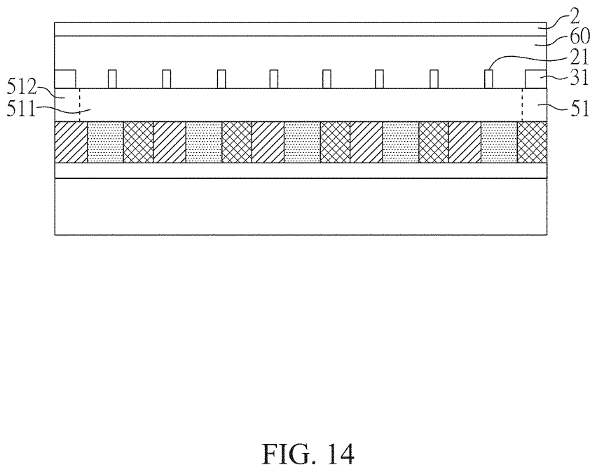

The preparation method of the touch panel 2003 of the present embodiment includes the steps of (1) coating a silver nanowire layer 2 on the cap layer 51 of the display panel 50 as shown in FIG. 11; (2) patterning the silver nanowire layer 2 through a photoresist exposure and development process to form the first conductive mesh film 21 in the display zone 511 and the first conducting wires 31 in the non-display zone 512 as shown in FIG. 12; (3) disposing the insulating layer 60 on the first conductive mesh film 21 and the first conducting wires 31 as shown in FIG. 13; (4) coating another silver nanowire layer 2 on the insulating layer 60 as shown in FIG. 14; (5) patterning the silver nanowire layer 2 through a photoresist exposure and development process to form the second conductive mesh film 22 with respect to the display zone 511 and the second conducting wires 32 with respect to the non-display zone 512 for finishing the touch panel 2003 shown in FIG. 10.

### Bending Test

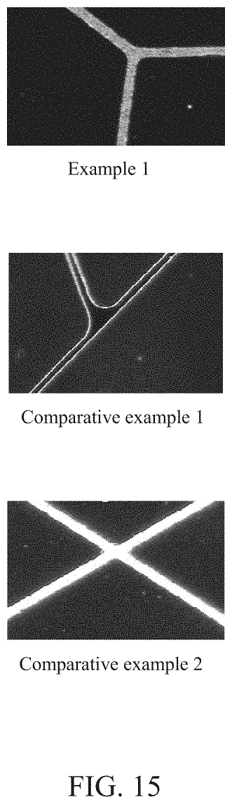

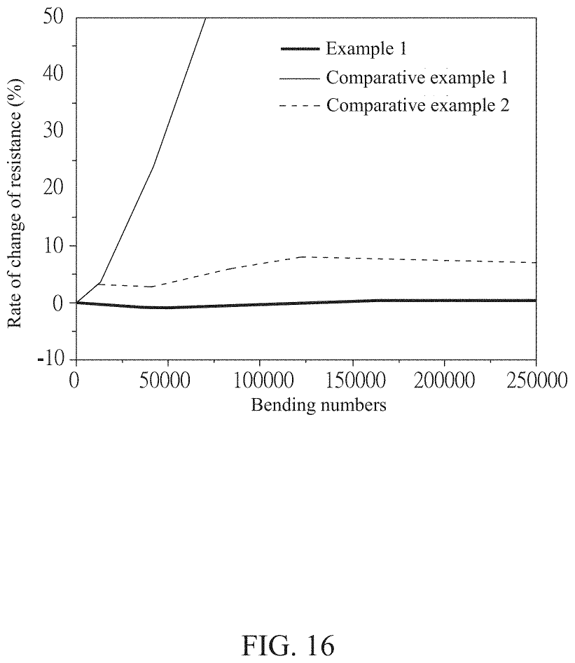

The present test example evaluates the flexibility of the transparent conductive film with three different metal meshes. The transparent conductive film 1000 of the first embodiment is applied in Example 1; the linewidth W of the silver nanowire areas 201 is 3 μm. A transparent conductive film with copper mesh as the conductive layer is applied in Comparative example 1; the linewidth of the copper mesh is 3.4 μm. A transparent conductive film with silver mesh comprising silver nanoparticles as the conductive layer is applied in Comparative example 2; the linewidth of the silver mesh is 5 μm. The mesh of Example 1, Comparative example 1, and Comparative example 2 are shown in FIG. 15. The bending conditions of the bending test are as follows. The resistance of the transparent conductive films of Example 1, Comparative example 1, and Comparative example 2 are measured under the bending conditions of 2 mm bending radius and 30 cycle/min bending rate, wherein those transparent conductive films are bent outwardly over 250,000 times. The results of the bending test are shown in FIG. 16. According to the results, the resistance of the transparent conductive film 1000 bent over 250,000 times remains unchanged; however, the resistance of the transparent conductive film of Comparative example 1 significantly increases with the increase in number of times bent, and the resistance of the transparent conductive film of Comparative example 2 slowly increases with the increase in number of times bent. As a result, the copper mesh of Comparative example 1 comprising continuous metal is easily broken when being bent; therefore, the resistance of the copper mesh significantly increases. The silver mesh of Comparative example 2 comprising silver nanoparticles, which is not continuous metal, has more tolerance to bending, so the resistance of the silver mesh of Comparative example 2 may decrease but still can be maintained around a certain value. On the contrary, the metal mesh of Example 1 comprises cross-bonded silver nanowires, which are more stable when being bent. Accordingly, the change rate of resistance of the metal mesh of Example 1 remains 0% after being bent more than 250,000 times, and the transparency of the transparent conductive film to visible light (having a wavelength between 400 nm and 700 nm) is 91%.

The above disclosure is related to the detailed technical contents and inventive features thereof. People skilled in the art may proceed with a variety of modifications and replacements based on the disclosures and suggestions of the disclosure as described without departing from the characteristics thereof. Nevertheless, although such modifications and replacements are not fully disclosed in the above descriptions, they have substantially been covered in the following claims as appended.

1. A transparent conductive film, comprising:
a substrate; and
a conductive mesh film disposed on the substrate,
wherein the conductive mesh film comprises a plurality of cross-bonded silver nanowires, and a rate of change of resistance of the conductive mesh film is smaller than 1% after bending the transparent conductive film over 250,000 times.

2. The transparent conductive film claimed in claim 1, wherein a transparency of the transparent conductive film to visible light is greater than 90%.

3. The transparent conductive film claimed in claim 1, wherein the conductive mesh film comprises a plurality of silver nanowire areas and a plurality of blank areas, the cross-bonded silver nanowires are disposed in the silver nanowire areas, a linewidth of each of the silver nanowire areas is 1 μm to 10 μm, and an area of each of the blank areas is 100 μm² to 200 μm².

4. The transparent conductive film claimed in claim 3, wherein a ratio of a total area of the blank areas to an area of the conductive mesh film is 0.9 to 0.999.

5. The transparent conductive film claimed in claim 1, wherein the conductive mesh film further comprises a hard-coated layer for coating or covering the cross-bonded silver nanowires.

6. The transparent conductive film claimed in claim 1, wherein the substrate comprises a display zone and a non-display zone, and the conductive mesh film is disposed on the display zone.

7. The transparent conductive film claimed in claim 6, further comprising a plurality of conducting wires disposed on the non-display zone of the substrate and electrically connected to the conductive mesh film, wherein the conducting wires comprise a plurality of cross-bonded silver nanowires.

8. A touch panel, comprising:
a first substrate having a first surface and a second surface opposing the first surface;
a first conductive mesh film disposed on the first surface of the first substrate; and
a second conductive mesh film disposed above the first surface of the first substrate or disposed on the second surface of the first substrate,
wherein the first conductive mesh film and the second conductive mesh film comprise a plurality of cross-bonded silver nanowires, and a rate of change of resistance of the first conductive mesh film and the second conductive mesh film is smaller than 1% after bending the touch panel over 250,000 times.

9. The touch panel as claimed in claim 8, further comprising a second substrate and an adhesive layer, wherein the second substrate comprises a first surface and a second surface opposing the first surface, the second conductive mesh film is disposed on the first surface of the second substrate, and the adhesive layer is disposed between the second surface of the second substrate and the first conductive mesh film.

10. The touch panel as claimed in claim 8, wherein the second conductive mesh film is disposed on the second surface of the first substrate.

11. The touch panel as claimed in claim 8, further comprising an insulating layer disposed on the first conductive mesh film, wherein the second conductive mesh film is disposed on the insulating layer.

12. The touch panel as claimed in claim 8, wherein the first conductive mesh film and the second conductive mesh film respectively have a plurality of silver nanowire areas and a plurality of blank areas, the cross-bonded silver nanowires are disposed in the silver nanowire areas, a linewidth of each of the silver nanowire areas is 1 μm to 10 μm, and an area of each of the blank areas is 100 μm² to 200 μm².

13. The touch panel as claimed in claim 12, wherein a ratio of a total area of the blank areas to an area of the first conductive mesh film is 0.9 to 0.999, and a ratio of a total area of the blank areas to an area of the second conductive mesh film is 0.9 to 0.999.

14. The touch panel as claimed in claim 8, wherein the first conductive mesh film and the second conductive mesh film respectively includes a hard-coated layer for coating or covering the cross-bonded silver nanowires.

15. The touch panel as claimed in claim 8, wherein the first substrate comprises a display zone and a non-display zone, the first conductive mesh film is disposed in the display zone, and the second conductive mesh film is disposed with respect to the display zone.

16. The touch panel as claimed in claim 15, further comprising a plurality of first conducting wires and a plurality of second conducting wires, wherein the first conducting wires are disposed on the non-display zone and are electrically connected to the first conductive mesh film, the second conducting wires are disposed with respect to the non-display zone and are electrically connected to the second conductive mesh film, and the first conducting wires and the second conducting wires are formed by a plurality of cross-bonded silver nanowires respectively.
